(19) United States
(12) Patent Application Publication
(10) Pub. No.: US 2026/0353775 A1
(43) Pub. Date: Nov. 5, 2026

(54) METHOD OF MAKING MESA REGION NANO SHEET DEVICE HAVING LEAKAGE REDUCTION BY HALO-IMP

(71) Applicant: TAIWAN SEMICONDUCTOR MANUFACTURING COMPANY, LTD., Hsinchu (TW)

(72) Inventors: Yu-Chang LIN, Hsinchu (TW); Liang-Yin CHEN, Hsinchu (TW); Huicheng CHANG, Hsinchu (TW); Yee-Chia YEO, Hsinchu (TW)

(21) Appl. No.: 19/744,426

(22) Filed: Jul. 16, 2026

Related U.S. Application Data
(62) Division of application No. 18/314,555, filed on May 9, 2023.

(51) Int. Cl. H10D 84/83; H10D 30/01; H10D 30/43; H10D 30/67; H10D 62/10; H10D 84/01; H10D 84/03

(52) U.S. Cl. CPC H10D 84/83; H10D 30/014; H10D 30/43; H10D 30/6735; H10D 30/6757; H10D 62/102; H10D 62/121; H10D 84/017; H10D 84/0191; H10D 84/038

(57) ABSTRACT

A method of manufacturing an integrated circuit device includes forming a well region having a first dopant concentration over a semiconductor substrate. The method further includes forming a stacked structure over a first region of the well region. The method further includes etching a first portion of the well region adjacent the stacked structure to form a first recess and a mesa region. The method further includes filling the first recess with an undoped epitaxial layer. The method further includes implanting a first dopant dose of a first dopant species at an implant energy into the undoped epitaxial layer to form a first doped epitaxial region. The method further includes forming a source/drain (S/D) structure over the first doped epitaxial region, wherein a second dopant concentration within the first doped epitaxial region is sufficient to shift a device junction away from the stacked structure.

### PRIORITY

This application is a divisional of U.S. application Ser. No. 18/314,555, filed May 9, 2023, the entire contents of which are hereby incorporated by reference.

### BACKGROUND

Semiconductor devices are used in a variety of electronic applications, such as personal computers, cell phones, digital cameras, and other electronic equipment. Semiconductor devices are fabricated by sequentially depositing insulating or dielectric layers, conductive layers, and semiconductor layers of material over a substrate, and patterning the various material layers using lithography to form circuit components and elements thereon. As the semiconductor industry has progressed into nanometer technology process nodes in pursuit of higher device density, improved performance, and lower costs, challenges from both fabrication and design issues have resulted in the development of a number of three-dimensional designs including, for example, Metal-Oxide-Silicon Field Effect Transistors (MOS-FET), Field Effect Transistors (FET), Fin Field Effect Transistor (FinFET), Gate-All-Around (GAA) devices (nanowires), and Multi-Bridge Channel Field Effect Transistor (MBCFET) devices (nanosheets).

Integrated circuit (IC) manufacturing processes are typically divided into front-end-of-line (FEOL) processing and back-end-of-line (BEOL) processing. FEOL processes generally encompass those processes related to fabricating functional elements, such as transistors and resistors, in or on a semiconductor substrate. For example, FEOL processes typically include forming isolation features, gate electrodes and dielectrics, and source and drain features (also referred to as source/drain or S/D features). BEOL processes generally encompass those processes related to fabricating a multilayer interconnect (MLI) features that interconnects the functional IC elements and structures fabricated during FEOL processing to provide connection to and enable operation of the resulting IC devices. Process and structural modifications that reduce the process complexity and/or size of features associated with, for example, gate electrodes and related structures and multilayer interconnect structures, tend to reduce the overall size of the IC devices, improve cycle time, and/or improve yield and reliability.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A-1F are cross-sectional views of a semiconductor device during a manufacturing process, according to some embodiments.

FIG. 2 is a cross-sectional view of a semiconductor device during a manufacturing process according to some embodiments.

FIG. 3 is a table of implant parameters according to some embodiments.

FIG. 4 is a flowchart of a manufacturing process for the production of IC devices according to some embodiments.

FIG. 5 is a schematic diagram of a system for manufacturing FET devices according to some embodiments.

FIG. 6 is a flowchart of IC device design, manufacture, and programming of IC devices according to some embodiments.

FIG. 7 is a schematic diagram of a processing system for manufacturing of IC devices according to some embodiments.

### DETAILED DESCRIPTION

The following disclosure provides many different embodiments, or examples, for implementing different features of the provided subject matter. Specific examples of components, values, operations, materials, arrangements, or the like, are described below to simplify the present disclosure. These are, of course, merely examples and are not intended to be limiting. Other components, values, operations, materials, arrangements, or the like, are contemplated. For example, the formation of a first feature over or on a second feature in the description that follows may include embodiments in which the first are formed in direct contact the second features and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The structures and methods detailed below relate generally to improved structures, designs, and manufacturing methods for IC devices that include source/drain regions arranged in close proximity to other regions, e.g., a mesa region of a well, that provide one or more potential current leakage paths as a result of drain induced barrier lowering (DIBL). Excessive leakage current tends to degrade the yield and/or performance of the resulting integrated circuits. Accordingly, in some embodiments adopting structures and methods that tend to reduce or eliminate such leakage current allows for reduced sizing of functional elements by decreasing extraneous physical separation and/or interruption of the leakage path degrade the yield and/or performance of the resulting integrated circuits.

Although the structures and methods will be discussed in terms of nanosheet (NS) devices, e.g., Multi-Bridge Channel Field Effect Transistor (MBCFETs), the structures and methods are not so limited and are suitable for inclusion in manufacturing processes for other classes and configurations of IC devices including, without limitation, bulk semiconductor devices and silicon-on-insulator (SOI) devices, Metal-Oxide-Silicon Field Effect Transistors (MOSFET or FET), Fin Field Effect Transistor (FinFET), Nano-Sheet Field Effect Transistor, Nano-Wire Field Effect Transistor, and Gate-All-Around (GAA) devices.

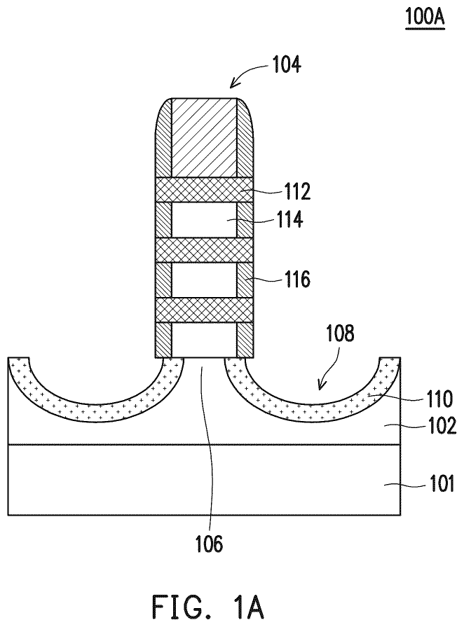

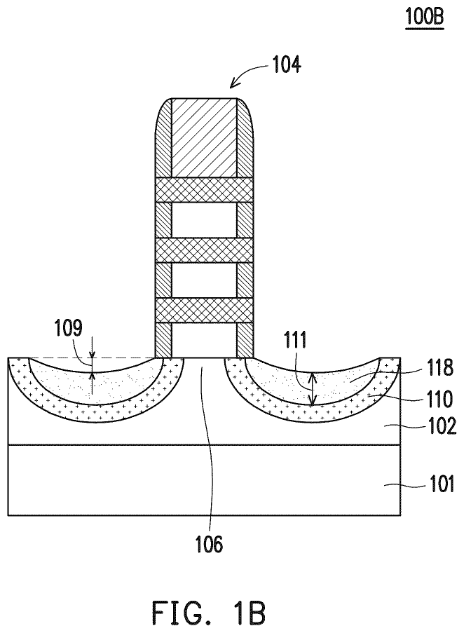

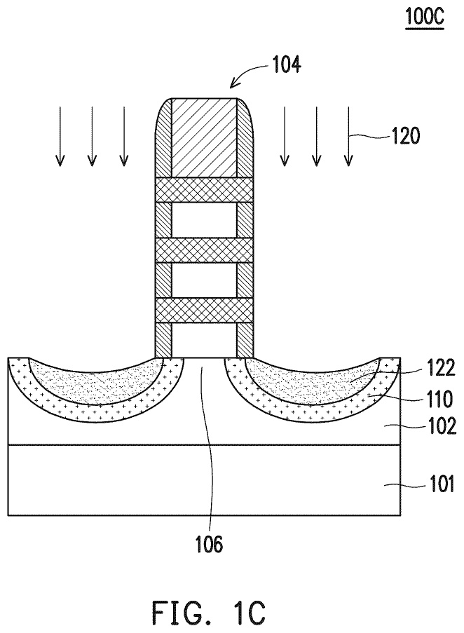

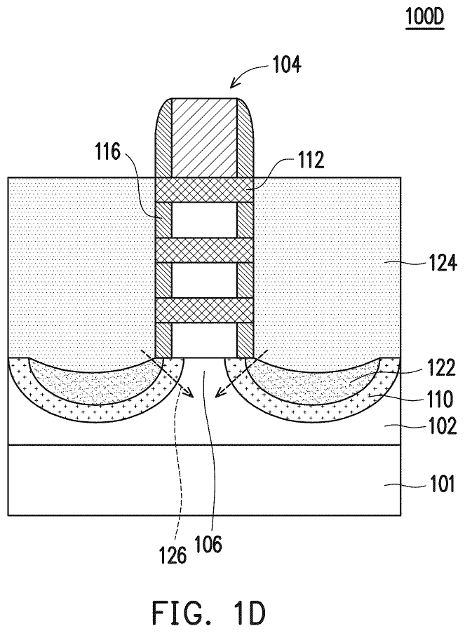

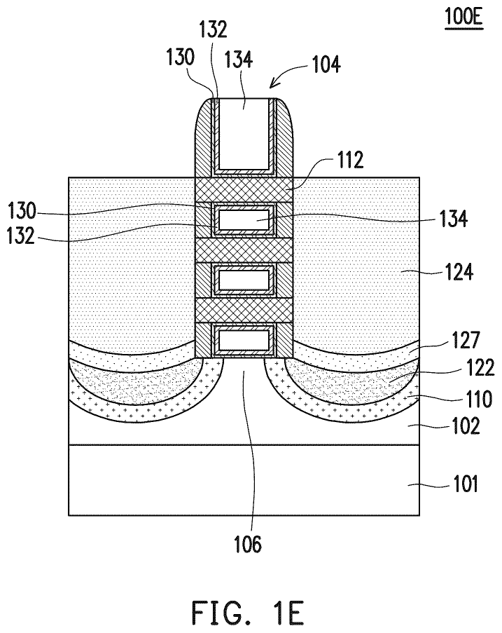

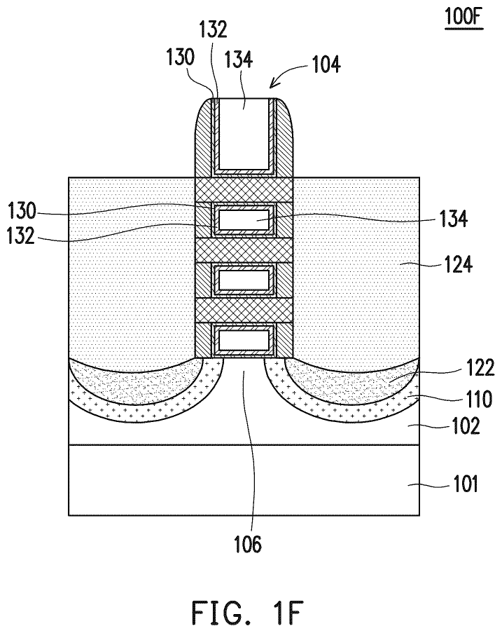

FIG. 1A is a cross-sectional view of a portion of an integrated circuit device at an intermediate operation during a manufacturing process according to some embodiments. The IC device 100A in FIG. 1A includes a well region 102 formed in or formed on a semiconductor substrate 101 and a stacked structure 104 formed above the mesa region 106 of the well region 102. The term stacked structure 104 is being used as an inclusive reference for the various materials and structures arranged in the composite vertical stack above the mesa region 106 at various stages of the manufacturing operation including, but not limited to, dummy gate structures, gate structures, gate dielectrics, channel regions, sidewalls, hard masks, and spacers. Portions of the well region 102 not covered by the stacked structure 104 are then etched to form recessed regions 108 on opposite sides of a residual mesa region 106 of the well region 102.

In some embodiments the etch parameters used in forming recessed regions 108 will result in some undercutting of the stacked structure 104 and increase the likelihood of parasitic leakage at that point. In some embodiments, an anti-doping implant is used to form anti-doping regions 110 in an upper portion of the well region 102 adjacent the stacked structure 104, under the recessed regions 108, and under the edges of the stacked structure 104. In some embodiments the anti-doping implant dopant concentration is between 5E¹⁸ cm⁻³ and 5E¹⁹ cm⁻³, e.g., 1E¹⁹ cm⁻³. In some embodiments, the anti-doping implant dopant concentration alters the location and/or the susceptibility of the junction associated with the parasitic leakage to a degree that meets a predetermined performance parameter. In some embodiments, the dopant, dopant concentration, and implant energy are selected for controlling the positioning of the transistor junction relative to the mesa region 106 as a means for suppressing current leakage.

In some embodiments, the etch process utilized in forming the mesa region 106 is performed using plasma etching, reactive ion etching (RIE), or a liquid chemical etch solution. In some embodiments a liquid chemical etch solution will include one or more etchants such as citric acid (C₆H₈O₇), hydrogen peroxide (H₂O₂), nitric acid (HNO₃), sulfuric acid (H₂SO₄), hydrochloric acid (HCl), acetic acid (CH₃CO₂H), hydrofluoric acid (HF), buffered hydrofluoric acid (BHF), phosphoric acid (H₃PO₄), ammonium fluoride (NH₄F) potassium hydroxide (KOH), ethylenediamine pyrocatechol (EDP), TMAH (tetramethylammonium hydroxide), or a combination thereof.

In some embodiments, the etching process is a dry-etch or plasma etch process performed using halogen-containing reactive gases excited by an electromagnetic field to dissociate into ions that are then accelerated toward the material being etched. Reactive or etchant gases include, for example, CF₄, SF6, NF3, Cl₂, CCl₂F₂, SiCl₄, BCl₂, and combinations thereof, although other semiconductor-material etchant gases are also envisioned within the scope of the present disclosure.

In some embodiments a series of alternating silicon (Si) layers 112 and silicon-germanium (SiGe) layers 114 are fabricated during the formation of stacked structure 104. In some embodiments a series of etching and deposition operations is then used to remove a portion of the silicon germanium layers 114 to form recessed regions (not shown) on the sidewalls that are bounded top and bottom by adjacent silicon layers 112. In some embodiments a dielectric spacer 116, e.g., silicon dioxide, silicon nitride, or a combination thereof, is then formed in the recessed regions, leaving the lateral surfaces of the silicon layers 112 exposed. In some embodiments, incorporating a larger number of layers in the series of alternating silicon (Si) layers 112 and silicon-germanium (SiGe) layers 114 will tend to increase the drive current, but the associated increase in contact resistance through the adjacent source/drain (S/D) regions to the lower layers to limit the gain in drive current and mitigates the advantages of larger numbers of layers. In some embodiments, the number of nanosheets utilized in the stacked structures is set between 3 and 4 layers for providing a satisfactory compromise between performance and manufacturability although other embodiments incorporate different numbers of nanosheets.

In some embodiments, the dielectric spacer 116 is formed using materials having a high dielectric constant (high-k), e.g., κ>3.9. In some embodiments, the high-k dielectric material includes one or more of HfO₂, TiO₂, HfZrO, Ta₂O₃, HfSiO₄, ZrO₂, ZrSiO₂, LaO, AlO, ZrO, TiO, Ta₂O₅, Y₂O₃, SrTiO₃ (STO), BaTiO₃ (BTO), BaZrO, HfZrO, HfLaO, HfSiO, LaSiO, AlSiO, HfTaO, HfTiO, (Ba,Sr)TiO₃ (BST), Al₂O₃, Si₃N₄, SiOₓN_{y}, and combinations thereof, or another suitable material. The insulating/dielectric materials may be formed by atomic layer deposition (ALD), physical vapor deposition (PVD), chemical vapor deposition CVD, plasma enhanced chemical vapor deposition (PECVD), thermal oxidation, self-aligned monolayer (SAM) deposition and/or one or more other suitable method(s).

The IC device 100A in FIG. 1A includes a series of nanoplates (NP) or nanosheets (NS) comprising silicon layers 112 that are embedded in a stacked structure 104. In some embodiments, the stacked structure 104 includes one or more conductive materials selected from a group including polysilicon, metals, metal alloys, and/or metal silicides. In some embodiments, the conductive material will include various combinations of materials to enhance the device performance and/or device longevity including, for example, a liner layer, a diffusion barrier layer, a wetting layer, an adhesion layer, a metal fill layer, and/or one or more other suitable layers. In some embodiments, the conductive material will be selected from Si, Ge, SiGe, Ti, Ag, Al, TiAlN, TaC, TaCN, TaSiN, Mn, Zr, TiN, TaN, Ru, Mo, Al, WN, Cu, W, Re, Ir, Co, Ni, and other conductive materials suitable for use in conjunction with polysilicon, silicides, and combinations and alloys thereof.

FIG. 1B is a cross-sectional view of a portion of an integrated circuit device at an intermediate operation subsequent to the operation illustrated in FIG. 1A and useful in manufacturing IC devices according to some embodiments. FIG. 1B is a cross-section view of the IC device 100B after deposition of a non-doped silicon epitaxial (NSE) layer 118 in recessed regions 108. In some embodiments the central region of the epitaxial layer 118 is recessed relative to both the peripheral region of the epitaxial layer and an upper surface of the mesa region 106 of the well region 102. In some embodiments the central and peripheral regions of the epitaxial layer 118 are both recessed relative to an upper surface of the mesa region 106 of the well region 102 (not labeled). A first distance between a first plane defined by an upper surface of the mesa region 106 of the well region 102 and the central surface region of the epitaxial layer 118 defines a NSE recess height 109 (RH). In some embodiments, the recessed and arcuate surface of the recessed regions 108 provide for deeper placement into the well region 102 of the halo implant. In some embodiments, the recessed and arcuate surface of the recessed region, in conjunction with a tilt implant, provide for placement of a portion of the halo implant further into the mesa region 106 and under an undercut edge portion of the stacked structure 104. If the recess 108 is too shallow, the halo implant will be placed above a thicker portion of the well region 102 and will not tend to extend as far under the edge of the stacked structure 104 even using a tilt implant. If the recess is too deep, the well region 102 will be unduly thinned and the impact of the halo implant near the mesa region 106 will be reduced. A second distance between the central surface region of the epitaxial layer 118 and a lower surface of the epitaxial layer 118 defines a NSE thickness 111 (T_{NSE}).

FIG. 1C is a cross-sectional view of a portion of an integrated circuit device at an intermediate operation subsequent to the operation illustrated in FIG. 1B and useful in manufacturing IC devices according to some embodiments. FIG. 1C is a cross-section view of the IC device 100C in which a halo implant is performed to implant one or more dopant species 120 into the epitaxial layer 118 and form a doped halo region 122 within the epitaxial layer 118. In some embodiments, the implant species are selected from a group consisting of n-type and p-type dopants including, for example, arsenic (As), phosphorus (P), antimony (Sb), boron (B), boron difluoride (BF₂), gallium (Ga), and combinations thereof. In some embodiments, a combination of the implant species and the implant energy are selected to produce an implant range that is less than the epitaxial thickness 111 (T_{NSE}) to ensure the majority of the implant dose remains within the epitaxial layer 118.

By limiting the majority of the implant dose to the epitaxial layer 118, the halo implant used in some embodiments limits or eliminates implant-induced damage in the well region 102 while still providing a level of doping that tends to suppress the flow of leakage current into the well region. In some embodiments, the implant species and the implant energy are selected to produce an implant range that is less than 85% of the NSE thickness 111 (T_{NSE}). In some embodiments, reducing the implant range to something less than the NSE thickness 111 is utilized to maintain a residual undoped buffer region (not shown) in the epitaxial layer 118 below the doped halo region 122. In some embodiments, the implant species and the implant energy are selected to produce an implant range approaches the NSE thickness 111 (T_{NSE}) to provide an increased thickness of the doped halo region 122 while still retaining the majority of the dopant within the epitaxial layer 118.

In some embodiments, the halo implant is conducted perpendicular to a plane defined by a surface of the substrate 101. In some embodiments, at least a portion of the halo implant is conducted as a tilted implant at an angle offset of up to 15° from perpendicular, i.e., a tilt angle that satisfies the expression 0<tilt angle≤15°. In some embodiments, using a tilted implant technique during the halo implant allows an increased portion of the implanted dopant species 120 to be placed adjacent to or within an upper peripheral region of the mesa region 106. The actual tilt angle used in the halo implant process will be dependent to some degree on the aspect ratio of the existing structures on the substrate with lower tilt angles being used with higher aspect ratio structures and higher tilt angles being used with lower aspect ratio structures. A tilt angle range of up to 15 degrees, i.e., 0<tilt angle≤15° will be suitable for a range of embodiments.

FIG. 1D is a cross-sectional view of a portion of an integrated circuit device at an intermediate operation subsequent to the operation illustrated in FIG. 1C and useful in manufacturing IC devices according to some embodiments. In some embodiments source/drain (S/D) structures 124 are epitaxially grown out from the exposed sidewalls of the Si layers 112 and dielectric spacers 116 and/or up from an upper surface of the doped halo region 122, providing both the S/D structures 124 and structural support for the stacked structure 104. The SiGe layers in the nanosheet stack are then selectively removed, exposing the Si channels. Subsequent atomic layer deposition (ALD) operations introduce the gate oxide stack, potentially with multiple work functions for device Vt offerings. In some embodiments, a subsequent ALD operation provides the gate material and fully encapsulates the nanosheet stack. As reflected in FIG. 1D, in some embodiments the placement of the doped halo regions 122 between the source/drain structures 124 and the mesa region 106 tends to suppress parasitic current leakage 126 along a path between the source/drain structures 124 and the mesa region 106 of the transistor. In some embodiments, the advantages of suppressing or eliminating the parasitic current leakage path 126 are reflected in an improved mesa pass rate (MPR) by as much as 20%.

FIG. 1E is a cross-sectional view of a portion of an integrated circuit device at an intermediate operation subsequent to the operation illustrated in FIG. 1C and useful in manufacturing IC devices according to some embodiments. In some embodiments source/drain (S/D) structures 124 are epitaxially grown out from the exposed sidewalls of the silicon layers 112 and/or up from an upper surface of the doped halo region 122, providing both the S/D structures 124 and structural support for the stacked structure 104. The device illustrated in FIG. 1E also includes an optional additional dielectric layer 127 is situated between an upper surface of the doped halo regions 122 and a lower surface of the source/drain structures 124. In some embodiments, this additional dielectric layer 127 provides additional separation and current suppression between the doped halo regions 122 and the source/drain structures 124. In some embodiments, the additional dielectric layer 127 may be formed from a silicon nitride (SiN) layer with a layer thickness of about 3-6 nm. In some embodiments, the thickness of the additional dielectric layer 127 is selected so as to avoid forming a layer that does not cover the silicon surface and interfere with subsequent processing

Some embodiments differ in the timing of the gate electrode construction and can be broadly separated into 1) gate first and 2) gate last processes (also known as replacement gate processes). In both gate first processes and gate last processes the goal is to produce IC devices that consistently exhibit the predetermined work functions and threshold voltages for both the N-type metal-oxide-semiconductor (NMOS) and P-type metal-oxide-semiconductor (PMOS) transistors. Studies have shown that the threshold voltage of an IC device is highly dependent on both the properties of the deposited material(s) and the subsequent processing steps to which those materials are exposed.

FIGS. 1E and 1F are a cross-sectional views of alternative intermediate operations that result in different embodiments of an integrated circuit device that includes doped halo regions 122. In the embodiments of FIGS. 1E and 1F the doped halo regions 122 provide both physical and electrical separation between the mesa region 106 of the well and the source/drain structures 124 that tends to suppress or eliminate current leakage. FIGS. 1E and 1F also provide additional detail regarding embodiments including configuration of certain of the conductive elements of the stacked structure 104 including, for example, the use of a dielectric layer 130, a high-k material layer 132, and a primary conductive element 134 (e.g., a gate electrode) for improving the performance and robustness of the final integrated circuit device constructed with the doped halo regions 122.

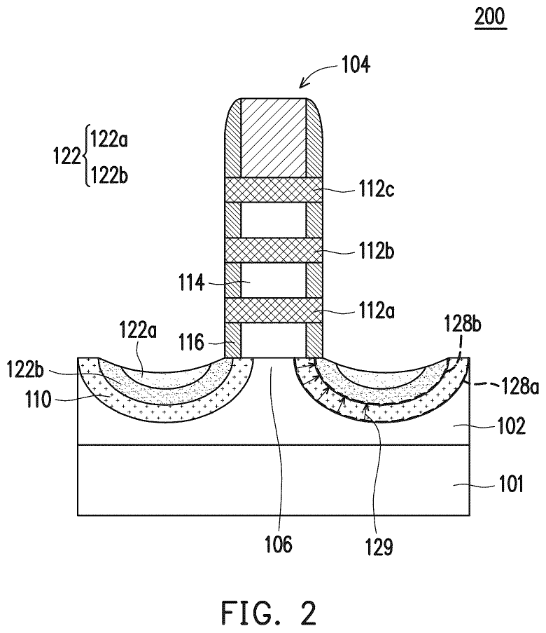

FIG. 2 is a cross-sectional view of an intermediate operation reflecting a non-uniform distribution in the halo implant dopant species 120 within the doped halo regions 122 of an integrated circuit device. In some embodiments, the combination of dopant species and implant energy is selected to provide a predetermined distribution throughout the initial undoped epitaxial layer 118 as it is converted by the halo implant operation to the final doped halo regions 122.

In some embodiments, the combination of dopant species and implant energy is selected to provide a more heavily doped upper region 122a that, for example, has a final dopant concentration of about 1E20 cm-3 and a less heavily doped intermediate and/or lower region 122b of the doped halo region 122 in which the final dopant concentration is about 5E19 cm-3. Final dopant concentrations above 1E²⁰ cm⁻³ require additional processing time, do not provide any additional benefit, and can result in higher concentrations at the well region 104/doped halo region 122b region boundary. Lower region dopant concentrations greater than about 5E¹⁹ cm⁻³ require additional processing time, induce additional implant damage, and do not appreciably increase the separation of the shifted junction 128b and the mesa region 106. In some embodiments, the final dopant concentration continues to decrease in those regions of the epitaxial layer 118 closer to the well and/or any anti-doping implant species introduced in a surface region of the well 102. In some embodiments, the final epitaxial layer doping profile includes an undoped or very lightly doped region adjacent the interface between the epitaxial layer 118 and the well 102 and/or an anti-doping implant region.

In some embodiments, the proximity of the more heavily doped halo regions 122 within the epitaxial layer 118 tends to shift or offset the parasitic transistor junction that forms between the source/drain regions 126 and the mesa region 106 under the first/lowest/bottom nanosheet 112a. As reflected in FIG. 2, the addition of the more heavily doped halo regions 122 tends to move the transistor junction toward the doped halo regions 122 and away from an original or unadjusted junction position 128a near the mesa region 106 by a shift distance 129 to a secondary or adjusted junction position 128b, thereby tending to suppress leakage current and the short channel effects that gives rise to such leakage paths 126 in some designs, thereby tending to improve performance and/or lifetime of the resulting integrated circuit devices manufactured in accord with the methods and structures detailed herein. Those of ordinary skill in the art guided by this disclosure can adjust the relationships between the thickness and profile of the epitaxial layer 118 and the dopant species, implant energy, implant dose, and implant tilt angle to achieve doped halo regions 122 that improve the performance of the resulting integrated circuit devices while protecting the crystalline integrity of the well region 102 and mesa region 106 from implant damage. By confining the halo implant dopant species 120 to the epitaxial layer 118 a process engineer gains the benefits of the junction offset without incurring a level of damage to the underlying elements that would unduly compromise the performance and/or lifetime of the resulting devices.

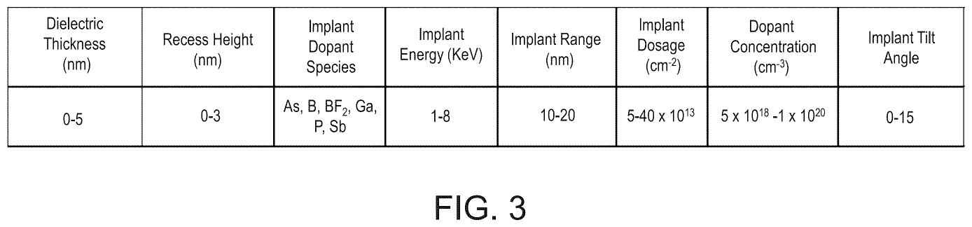

FIG. 3 is a chart reflecting various combinations of S/D configurations, implant species, implant energies, implant ranges, implant doses, implant concentration and implant tilt angle that are used by some embodiments of the invention. As reflected in the chart provided in FIG. 3, some embodiments, specifically the embodiments on rows 1-12, include a dielectric layer (see, dielectric layer 127 in FIG. 1E) between the doped halo region 122 and the S/D structures 124, having a dielectric thickness range of about 1-3 nm for the embodiments on rows 1-6, and a thickness range of about 3-5 nm for the embodiments on rows 7-12. As also reflected in FIG. 3, some embodiments, specifically the embodiments on rows 13-24, do not include a dielectric layer between the doped halo region 122 and the S/D structures 124 so that the S/D structures are formed directly on the doped halo region.

As reflected in FIG. 3 the implant energy is adjusted for both the particular dopant being used and the thickness of the dielectric with the embodiments on rows 7-12 using higher implant energies than the embodiments on rows 1-12 to achieve the target implant range of 10-20 nm and ensure that the doped halo region 122 exhibits the predetermined dopant concentration values and doping profile. As reflected in FIG. 3 the implant dosage is selected from a series of incremental implant doses ranging from a minimum of 5×10¹³ cm⁻² for each of the dopants to a maximum of 40'10¹³ cm⁻² for phosphorus and boron. In consideration of the configuration and thickness of the epitaxial layer 118 and the dopant, the operator applies the particular combination of implant dosage and implant energy to obtain a dopant concentration of between 5×10¹⁸ and 1×10²⁰ cm⁻³ in the doped halo region 122.

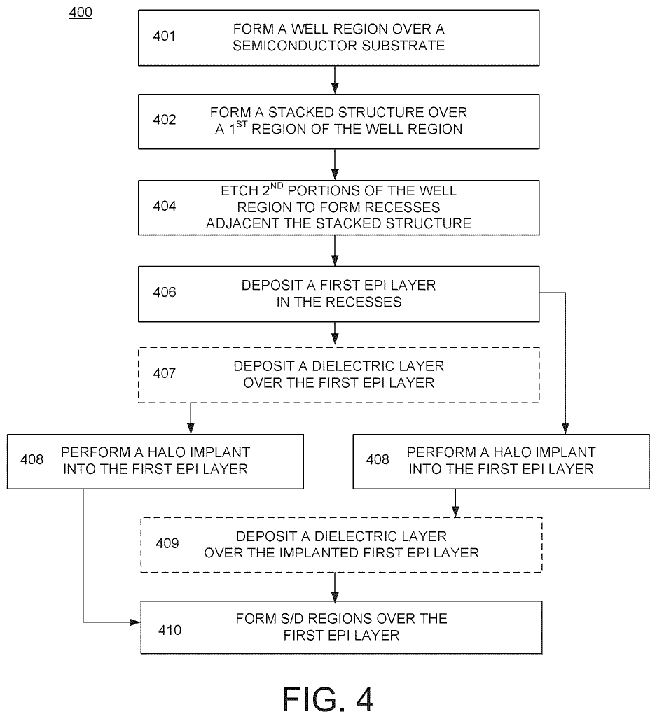

As reflected in FIG. 3, certain of the embodiments that do not include a dielectric layer between the doped halo region 122 and the S/D structures 124 do include recessed upper surface on the epitaxial layer 118 with the embodiments on rows 13-18 having a recess height (RH) of about 1 nm and the embodiments on rows 19-24 having a recess height of about 3 nm. In some embodiments, the recess height is a factor in setting the aspect ratio of the surface structures and affects the tilt angle used for the halo implant to ensure suppression of short channel effects (SCE) associated with shorter channel lengths. In some embodiments the dielectric layer thickness can be increased to reduce or suppress leakage, but an overly thick dielectric layer will cover the bottom sheet and interfere with subsequence processing. FIG. 4 is a flowchart of a process 400 for manufacturing IC devices according to some embodiments. In some embodiments, manufacturing process 400 is used to manufacture IC devices according to the operations illustrated in FIGS. 1A-F and references to the structures identified above in connection with FIGS. 1A-F are incorporated below to aid in the understanding the flowchart of FIG. 4 and not by way of limiting the application of the manufacturing process 400 to only the embodiments of FIGS. 1A-F.

Embodiments according to FIG. 4 include operation 402 during which the substrate, e.g., a semiconductor substrate 101, is prepared and certain front end of line (FEOL) operations including, for example, depositing layer(s) of materials, implanting, annealing, and patterning and etching the deposited materials, are completed to manufacture, for example, well regions, isolation structures (not shown),, source/drain structures 124, and stacked structures 104. In some embodiments one or more of the layers of material applied to the surface of the substrate during formation of the stacked structure 104 is/are planarized using etchback and/or CMP processes to prepare the surface for subsequent processing. Details regarding the execution of processes utilized in performing operation 402 are detailed above in connection with the discussion of FIGS. 1A-F according to some embodiments.

In operation 404 exposed portions of the well region 102 are etched using the stacked structure 104 as an etch mask for forming self-aligned recessed regions 108 on opposite sides of the stacked structure 104 and leaving a residual portion of the well region 102 to form an elevated mesa region 106 under the stacked structure.

In operation 406 one or more epitaxial materials is/are deposited on the semiconductor device to fill, at least partially, the recessed regions 108 that were etched into the well region adjacent the stacked structure 104 in operation 404. In some embodiments, the final thickness of the epitaxial deposition is selected to produce an undoped epitaxial layer that has an upper surface at least a portion of which is recessed (characterized as a recess height (RH)) relative to a plane defined by an upper surface of the mesa region 106 under the stacked structure 104. In other embodiments, the final thickness of the epitaxial deposition is selected to produce an undoped epitaxial layer of sufficient thickness that all or substantially all of the subsequent halo implant dose remains within the undoped epitaxial layer.

In some embodiments an optional operation 407 is utilized for forming a dielectric layer 127 over the epitaxial layer 118 before the halo implant to provide additional spacing between the mesa region 106 and the source/drain structures 124 and provide additional suppression of short channel effects and the associated parasitic leakage. In some embodiments, the dielectric region(s) are utilized to reduce or suppress with the best results being seen in those devices that utilize both the halo implant and one or more dielectric layers.

In operation 408 a halo implant is utilized to selectively dope the previously undoped epitaxial layer. In some embodiments, the combination of dopant species and implant energy are selected to ensure that that all or substantially all of the subsequent implant dose of dopant species 120 remains within the epitaxial layer 118. In embodiments in which a dielectric layer 127 is formed before the halo implant, the implant energy and/or implant dose are increased to compensate for the additional materials through which the implant dopants must pass to reach the epitaxial layer and ensure that the final dopant concentration and distribution within the doped halo region are within predetermined limits. By limiting the projected range of the halo implant to something less than the thickness (T_{NSE}) of the epitaxial layer 118 the process 400 ensures that the well region 102 doping and any dopants introduced into the well region prior anti-doping implant dopant 110 concentrations are unaffected by the halo implant dopant species 120. In some embodiments, the combination of dopant species and implant energy are selected to ensure that the transistor junction region is shifted from an initial junction position 128a toward a second junction position 128b closer to the doped halo region 122 and, consequently, further away from the portion of the mesa region 106 underlying the first nanosheet silicon layer 112 in the stacked structure 104 that forms a portion of a parasitic current leakage path 126.

In some embodiments in which optional operation 407 was not performed, an optional operation 409 is utilized for forming a dielectric layer 127 over the doped halo region 122 to provide additional spacing between the mesa region 106 and the source/drain structures 124 and provide additional suppression of short channel effects and the associated parasitic leakage. In embodiments in which a dielectric layer 127 is formed after the halo implant, the implant energy and/or implant dose to not need to be adjusted to compensate for the additional materials and the implant calculations may be made with only consideration of the thickness of the epitaxial layer to ensure that the final dopant concentration and distribution within the doped halo region are within predetermined limits. In some embodiments the implant energy is increased for the halo implant to allow for penetration of the dopant(s) through a pre-existing dielectric layer. In these embodiments the dielectric layer provides some additional protection for the underlying semiconductor material(s). Alternatively, in some embodiments the halo implant is conducted before formation of the dielectric layer. In these embodiments, the halo implant can be conducted at lower implant energies that will tend to produce less implant damage and associated defects In some embodiments the dielectric layer is a multilayer structure that includes a diffusion barrier layer to isolate the S/D doping from the halo doping. In other embodiments, the dielectric layer is a layer of a single material that serves to isolate S/D EPI as well.

In operation 410, in some embodiments the source/drain regions 124 are formed using ALD or other suitable technique to form the source/drain structures over the doped halo regions between adjacent stacked structures 104 and/or isolation structures (not shown) arranged between active regions of the semiconductor substrate 101.

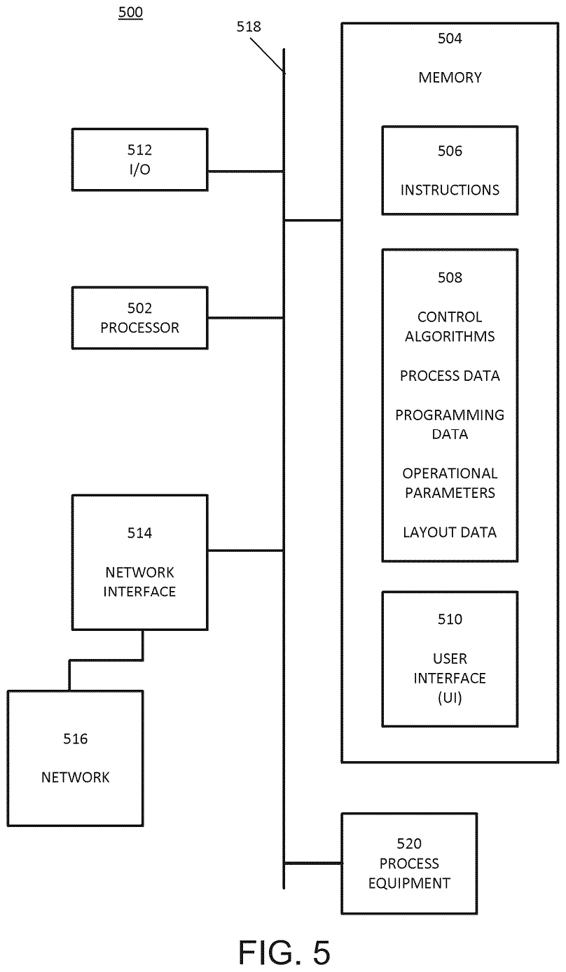

FIG. 5 is a block diagram of an electronic process control (EPC) system 500, in accordance with some embodiments. Methods used for generating cell layout diagrams corresponding to some embodiments of the FET device structures detailed above, particularly with respect to the addition and placement of the electrical contacts, thermal contacts, active metal patterns, dummy metal patterns, and other heat dissipating structures may be implemented, for example, using EPC system 500, in accordance with some embodiments of such systems.

In some embodiments, EPC system 500 is a general purpose computing device including a hardware processor 502 and a non-transitory, computer-readable, storage medium 504. Computer-readable storage medium 504, amongst other things, is encoded with, i.e., stores, computer program code (or instructions) 506, i.e., a set of executable instructions. Execution of computer program code 506 by hardware processor 502 represents (at least in part) an EPC tool which implements a portion or all of, e.g., the methods described herein in accordance with one or more (hereinafter, the noted processes and/or methods).

Hardware processor 502 is electrically coupled to computer-readable storage medium 504 via a bus 518. Hardware processor 502 is also electrically coupled to an I/O interface 512 by bus 518. A network interface 514 is also electrically connected to hardware processor 502 via bus 518. Network interface 514 is connected to a network 516, so that hardware processor 502 and computer-readable storage medium 504 are capable of connecting to external elements via network 516. Hardware processor 502 is configured to execute computer program code 506 encoded in computer-readable storage medium 504 in order to cause the EPC system 500 to be usable for performing a portion or all of the noted processes and/or methods. In one or more embodiments, hardware processor 502 is a central processing unit (CPU), a multi-processor, a distributed processing system, an application specific integrated circuit (ASIC), and/or a suitable processing unit.

In one or more embodiments, computer-readable storage medium 504 is an electronic, magnetic, optical, electromagnetic, infrared, and/or a semiconductor system (or apparatus or device). For example, computer-readable storage medium 504 includes a semiconductor or solid-state memory, a magnetic tape, a removable computer diskette, a random access memory (RAM), a read-only memory (ROM), a rigid magnetic disk, and/or an optical disk. In one or more embodiments using optical disks, computer-readable storage medium 504 includes a compact disk-read only memory (CD-ROM), a compact disk-read/write (CD-R/W), and/or a digital video disc (DVD).

In one or more embodiments, computer-readable storage medium 504 stores computer program code 506 configured to cause the EPC system 500 (where such execution represents (at least in part) the EPC tool) to be usable for performing a portion or all of the noted processes and/or methods. In one or more embodiments, computer-readable storage medium 504 also stores information which facilitates performing a portion or all of the noted processes and/or methods. In one or more embodiments, computer-readable storage medium 504 stores process control data 508 including, in some embodiments, control algorithms, process variables and constants, target ranges, set points, programming control data, and code for enabling statistical process control (SPC) and/or model predictive control (MPC) based control of the various processes.

EPC system 500 includes I/O interface 512. I/O interface 512 is coupled to external circuitry. In one or more embodiments, I/O interface 512 includes a keyboard, keypad, mouse, trackball, trackpad, touchscreen, and/or cursor direction keys for communicating information and commands to hardware processor 502.

EPC system 500 also includes network interface 514 coupled to hardware processor 502. Network interface 514 allows EPC system 500 to communicate with network 516, to which one or more other computer systems are connected. Network interface 514 includes wireless network interfaces such as BLUETOOTH, WIFI, WIMAX, GPRS, or WCDMA; or wired network interfaces such as ETHERNET, USB, or IEEE-1364. In one or more embodiments, a portion or all of noted processes and/or methods, is implemented in two or more EPC systems 500.

EPC system 500 is configured to send information to and receive information from fabrication tools 520 that include one or more of ion implant tools, etching tools, deposition tools, coating tools, rinsing tools, cleaning tools, chemical-mechanical planarizing (CMP) tools, testing tools, inspection tools, transport system tools, and thermal processing tools that will perform a predetermined series of manufacturing operations to produce the desired integrated circuit devices. The information includes one or more of operational data, parametric data, test data, and functional data used for controlling, monitoring, and/or evaluating the execution, progress, and/or completion of the specific manufacturing process. The process tool information is stored in and/or retrieved from computer-readable storage medium 504.

EPC system 500 is configured to receive information through I/O interface 512. The information received through I/O interface 512 includes one or more of instructions, data, programming data, design rules that specify, e.g., layer thicknesses, spacing distances, structure and layer resistivity, and feature sizes, process performance histories, target ranges, set points, and/or other parameters for processing by hardware processor 502. The information is transferred to hardware processor 502 via bus 518. EPC system 500 is configured to receive information related to a user interface (UI) through I/O interface 512. The information is stored in computer-readable medium 504 as user interface (UI) 510.

In some embodiments, a portion or all of the noted processes and/or methods is implemented as a standalone software application for execution by a processor. In some embodiments, a portion or all of the noted processes and/or methods is implemented as a software application that is a part of an additional software application. In some embodiments, a portion or all of the noted processes and/or methods is implemented as a plug-in to a software application. In some embodiments, at least one of the noted processes and/or methods is implemented as a software application that is a portion of an EPC tool. In some embodiments, a portion or all of the noted processes and/or methods is implemented as a software application that is used by EPC system 500.

In some embodiments, the processes are realized as functions of a program stored in a non-transitory computer readable recording medium. Examples of a non-transitory computer readable recording medium include, but are not limited to, external/removable and/or internal/built-in storage or memory unit, e.g., one or more of an optical disk, such as a DVD, a magnetic disk, such as a hard disk, a semiconductor memory, such as a ROM, a RAM, a memory card, and the like.

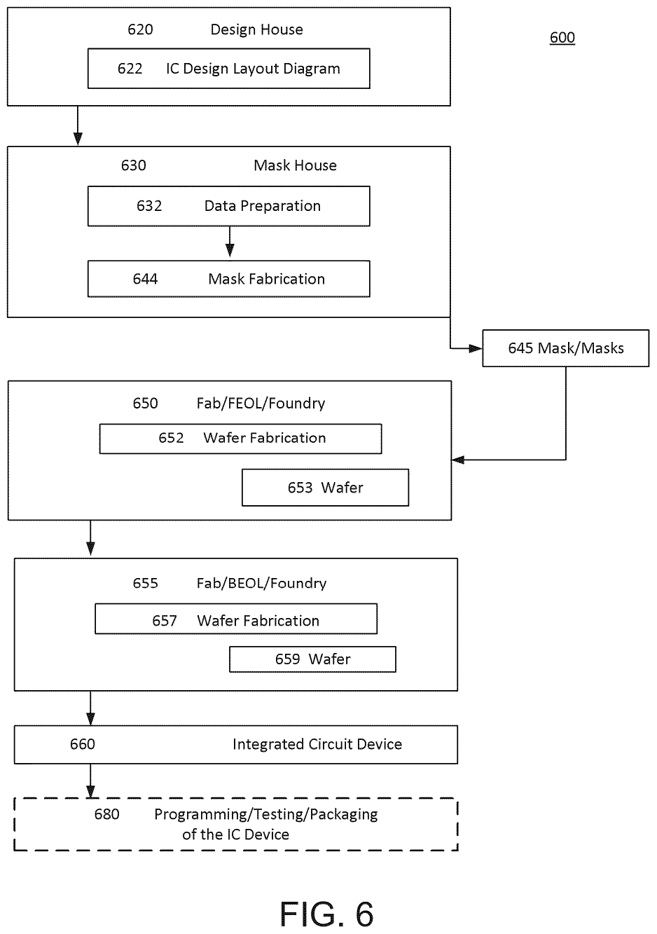

FIG. 6 is a block diagram of an integrated circuit (IC) manufacturing system 600, and an IC manufacturing flow associated therewith, in accordance with some embodiments for manufacturing IC devices that incorporate the improved control over the SSD and EPI profile. In some embodiments, based on a layout diagram, at least one of (A) one or more semiconductor masks or (B) at least one component in a layer of a semiconductor integrated circuit is fabricated using manufacturing system 600.

In FIG. 6, IC manufacturing system 600 includes entities, such as a design house 620, a mask house 630, and an IC manufacturer/fabricator (“fab”) 650, that interact with one another in the design, development, and manufacturing cycles and/or services related to manufacturing an IC device 660. Once the manufacturing process has been completed to form a plurality of IC devices on a wafer, the wafer is optionally sent to backend or back end of line (BEOL) 680 for, depending on the device, programming, electrical testing, and packaging in order to obtain the final IC device products. The entities in manufacturing system 600 are connected by a communications network. In some embodiments, the communications network is a single network. In some embodiments, the communications network is a variety of different networks, such as an intranet and the Internet.

The communications network includes wired and/or wireless communication channels. Each entity interacts with one or more of the other entities and provides services to and/or receives services from one or more of the other entities. In some embodiments, two or more of design house 620, mask house 630, and IC Fab 650 is owned by a single larger company. In some embodiments, two or more of design house 620, mask house 630, and IC Fab 650 coexist in a common facility and use common resources.

Design house (or design team) 620 generates an IC design layout diagram 622. IC design layout diagram 622 includes various geometrical patterns designed for an IC device 660. The geometrical patterns correspond to patterns of metal, oxide, or semiconductor layers that make up the various components of IC device 660 to be fabricated. The various layers combine to form various IC features.

For example, a portion of IC design layout diagram 622 includes various IC features, such as an active region, gate electrode, source and drain, metal lines or vias of an intermetal interconnection, and openings for bonding pads, to be formed in a semiconductor substrate (such as a silicon wafer) and various material layers disposed on the semiconductor substrate. Design house 620 implements a proper design procedure to form IC design layout diagram 622. The design procedure includes one or more of logic design, physical design or place and route. IC design layout diagram 622 is presented in one or more data files having information of the geometrical patterns. For example, IC design layout diagram 622, in some operations, will be expressed in a GDSII file format or DFII file format.

Whereas the pattern of a modified IC design layout diagram is adjusted by an appropriate method in order to, for example, reduce parasitic capacitance of the integrated circuit as compared to an unmodified IC design layout diagram, the modified IC design layout diagram reflects the results of changing positions of conductive line in the layout diagram, and, in some embodiments, inserting to the IC design layout diagram, features associated with capacitive isolation structures to further reduce parasitic capacitance, as compared to IC structures having the modified IC design layout diagram without features for forming capacitive isolation structures located therein.

Mask house 630 includes mask data preparation 632 and mask fabrication 644. Mask house 630 uses IC design layout diagram 622 to manufacture one or more masks 645 to be used for fabricating the various layers of IC device 660 according to IC design layout diagram 622. Mask house 630 performs mask data preparation 632, where IC design layout diagram 622 is translated into a representative data file (“RDF”). Mask data preparation 632 provides the RDF to mask fabrication 644. Mask fabrication 644 includes a mask writer. A mask writer converts the RDF to an image on a substrate, such as a mask (reticle) 645 or a semiconductor wafer 653. The IC design layout diagram 622 is manipulated by mask data preparation 632 to comply with particular characteristics of the mask writer and/or requirements of IC Fab 650. In FIG. 6, mask data preparation 632 and mask fabrication 644 are illustrated as separate elements. In some embodiments, mask data preparation 632 and mask fabrication 644 are collectively referred to as mask data preparation.

In some embodiments, mask data preparation 632 includes optical proximity correction (OPC) which uses lithography enhancement techniques to compensate for image errors, such as those that are known to arise from diffraction, interference, other process effects and the like. OPC adjusts IC design layout diagram 622. In some embodiments, mask data preparation 632 includes further resolution enhancement techniques (RET), such as off-axis illumination, sub-resolution assist features, phase-shifting masks, other suitable techniques, and the like or combinations thereof. In some embodiments, inverse lithography technology (ILT) is also used, which treats OPC as an inverse imaging problem.

In some embodiments, mask data preparation 632 includes a mask rule checker (MRC) that checks the IC design layout diagram 622 that has undergone processes in OPC with a set of mask creation rules which contain certain geometric and/or connectivity restrictions to ensure sufficient margins, to account for variability in semiconductor manufacturing processes, and the like. In some embodiments, the MRC modifies the IC design layout diagram 622 to compensate for limitations during mask fabrication 644, which may undo part of the modifications performed by OPC in order to meet mask creation rules.

In some embodiments, mask data preparation 632 includes lithography process checking (LPC) that simulates processing that will be implemented by IC Fab 650 to fabricate IC device 660. LPC simulates this processing based on IC design layout diagram 622 to create a simulated manufactured device, such as IC device 660. In some embodiments, the processing parameters in LPC simulation will include parameters associated with various processes of the IC manufacturing cycle, parameters associated with tools used for manufacturing the IC, and/or other aspects of the manufacturing process. LPC accounts for various factors, such as aerial image contrast, depth of focus (“DOF”), mask error enhancement factor (“MEEF”), other suitable factors, and the like or combinations thereof. In some embodiments, after a simulated manufactured device has been created by LPC, if the simulated device is not close enough in shape to satisfy design rules, OPC and/or MRC are be repeated to further refine IC design layout diagram 622.

It should be understood that the above description of mask data preparation 632 has been simplified for the purposes of clarity. In some embodiments, mask data preparation 632 includes additional features such as a logic operation (LOP) to modify the IC design layout diagram 622 according to manufacturing rules. Additionally, the processes applied to IC design layout diagram 622 during mask data preparation 632 may be executed in a variety of different orders.

After mask data preparation 632 and during mask fabrication 644, a mask 645 or a group of masks 645 are fabricated based on the modified IC design layout diagram 622. In some embodiments, mask fabrication 644 includes performing one or more lithographic exposures based on IC design layout diagram 622. In some embodiments, an electron-beam (e-beam) or a mechanism of multiple e-beams is used to form a pattern on a mask (photomask or reticle) 645 based on the modified IC design layout diagram 622. Mask 645will be formed using a process selected from various available technologies. In some embodiments, mask 645 is formed using binary technology. In some embodiments, a mask pattern includes opaque regions and transparent regions. A radiation beam, such as an ultraviolet (UV) beam, used to expose the image sensitive material layer (e.g., photoresist) which has been coated on a wafer, is blocked by the opaque region and transmits through the transparent regions. In one example, a binary mask version of mask 645 includes a transparent substrate (e.g., fused quartz) and an opaque material (e.g., chromium) coated in the opaque regions of the binary mask.

In another example, mask 645 is formed using a phase shift technology. In a phase shift mask (PSM) version of mask 645, various features in the pattern formed on the phase shift mask are configured to have proper phase difference to enhance the resolution and imaging quality. In various examples, the phase shift mask will be attenuated PSM or alternating PSM. The mask(s) generated by mask fabrication 644 is used in a variety of processes. For example, such a mask(s) is used in an ion implantation process to form various doped regions in semiconductor wafer 653, in an etching process to form various etching regions in semiconductor wafer 653, and/or in other suitable processes.

IC Fab 650 includes wafer fabrication 652. IC Fab 650 is an IC fabrication business that includes one or more manufacturing facilities for the fabrication of a variety of different IC products. In some embodiments, IC Fab 650 is a semiconductor foundry. For example, there may be a manufacturing facility for the front end fabrication of a plurality of IC products (front-end-of-line (FEOL) fabrication), while a second manufacturing facility may provide the back end fabrication for the interconnection and packaging of the IC products (back-end-of-line (BEOL) fabrication), and a third manufacturing facility may provide other services for the foundry business.

Wafer fabrication 652 includes forming a patterned layer of mask material formed on a semiconductor substrate is made of a mask material that includes one or more layers of photoresist, polyimide, silicon oxide, silicon nitride (e.g., Si₃N₄, SiON, SiC, SiOC), or combinations thereof. In some embodiments, masks 645 include a single layer of mask material. In some embodiments, a mask 645 includes multiple layers of mask materials.

In some embodiments IC Fab 655 includes wafer fabrication 657. IC Fab 655 is an IC fabrication business that includes one or more manufacturing facilities for the fabrication of a variety of different IC products. In some embodiments, IC Fab 655 is a manufacturing facility provide the back end fabrication for the interconnection and packaging of the IC products (back-end-of-line (BEOL) fabrication) to add one or more metallization layers to wafer 659, and a third manufacturing facility (not shown) may provide other services for the foundry business such as packaging and labelling.

In some embodiments, the mask material is patterned by exposure to an illumination source. In some embodiments, the illumination source is an electron beam source. In some embodiments, the illumination source is a lamp that emits light. In some embodiments, the light is ultraviolet light. In some embodiments, the light is visible light. In some embodiments, the light is infrared light. In some embodiments, the illumination source emits a combination of different (UV, visible, and/or infrared) light.

In some embodiments, etching processes include presenting the exposed structures in the functional area(s) to an oxygen-containing atmosphere to oxidize an outer portion of the exposed structures, followed by a chemical trimming process such as plasma-etching or liquid chemical etching, as described above, to remove the oxidized material and leave behind a modified structure. In some embodiments, oxidation followed by chemical trimming is performed to provide greater dimensional selectivity to the exposed material and to reduce a likelihood of accidental material removal during a manufacturing process. In some embodiments, the exposed structures may include the fin structures of Fin Field Effect Transistors (FinFET) with the fins being embedded in a dielectric support medium covering the sides of the fins. In some embodiments, the exposed portions of the fins of the functional area are top surfaces and sides of the fins that are above a top surface of the dielectric support medium, where the top surface of the dielectric support medium has been recessed to a level below the top surface of the fins, but still covering a lower portion of the sides of the fins.

Subsequent to mask patterning operations, areas not covered by the mask are etched to modify a dimension of one or more structures within the exposed area(s). In some embodiments, the etching is performed using plasma etching, reactive ion etching (RIE), or a liquid chemical etch solution, according to some embodiments. The chemistry of the liquid chemical etch solution includes one or more of etchants such as citric acid (C₆H₈O₇), hydrogen peroxide (H₂O₂), nitric acid (HNO₃), sulfuric acid (H₂SO₄), hydrochloric acid (HCl), acetic acid (CH₃CO₂H), hydrofluoric acid (HF), buffered hydrofluoric acid (BHF), phosphoric acid (H₃PO₄), ammonium fluoride (NH₄F) potassium hydroxide (KOH), ethylenediamine pyrocatechol (EDP), TMAH (tetramethylammonium hydroxide), or a combination thereof.

In some embodiments, the etching process is a dry-etch or plasma etch process. Plasma etching of a substrate material is performed using halogen-containing reactive gasses excited by an electromagnetic field to dissociate into ions. Reactive or etchant gases include, for example, CF₄, SF6, NF3, Cl₂, CCl2F2, SiCl₄, BCl₂, or a combination thereof, although other semiconductor-material etchant gases are also envisioned within the scope of the present disclosure. Ions are accelerated to strike exposed material by alternating electromagnetic fields or by fixed bias according to methods of plasma etching that are known in the art.

In some embodiments, molecular level processing technologies that share the self-limiting surface reaction characteristics utilized in ALD including, for example, Molecular Layer Deposition (MLD) and Self-Assembled Monolayers (SAM). MLD utilizes successive precursor-surface reactions in which a precursor is introduced into a reaction zone above the wafer surface. The precursor adsorbs to the wafer surface where it is confined by physisorption. The precursor then undergoes a quick chemisorption reaction with a number of active surface sites, leading to the self-limiting formation of molecular attachments in specific assemblies or regularly recurring structures. These MLD structures will be formed successfully using lower process temperatures than some traditional deposition techniques.

SAM is a deposition technique that involves the spontaneous adherence of organized organic structures on a wafer surface. This adherence involves adsorption of the organic structures from the vapor or liquid phase utilizing relatively weak interactions with the wafer surface. Initially, the structures are adsorbed on the surface by physisorption through, for instance, van der Waals forces or polar interactions. The self-assembled monolayers will then become confined to the surface by a chemisorption process. In some embodiments, the ability of SAM to grow layers as thin as a single molecule through chemisorption-driven interactions with the wafer surface(s) will be particularly useful in forming thin films including, for example, “near-zero-thickness” activation or barrier layers. SAM will also be particularly useful in area-selective deposition (ASD) (or area-specific deposition) using molecules that exhibit preferential reactions with specific segments of the underlying wafer surface in order to facilitate or obstruct subsequent material growth in the targeted areas. In some embodiments, SAM is used to form a foundation or blueprint region for subsequent area-selective ALD (AS-ALD) or area-selective CVD (AS-CVD).

The ALD, MLD, and SAM processes represent viable options for manufacturing thin layers (in some embodiments, the manufactured layers are only few atoms thick) that exhibit sufficient uniformity, conformality, and/or purity for the intended IC device application. By delivering the constituents of the material systems being manufactured both individually and sequentially into the processing environment, these processes and the precise control of the resulting surface chemical reactions allow for excellent control of processing parameters and the target composition and performance of the resulting film(s).

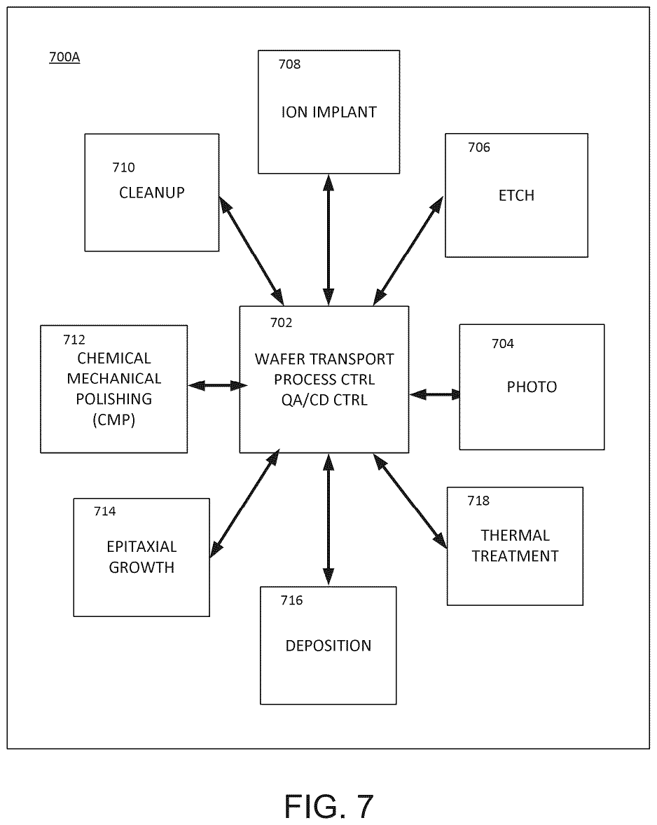

FIG. 7 is a schematic diagram of various processing departments defined within a Fab/Front End/Foundry for manufacturing IC devices according to some embodiments. The processing departments utilized in both front end of line (FEOL) and back end of line (BEOL) IC device manufacturing typically include a wafer transport operation 702 for moving the wafers between the various processing departments. In some embodiments, the wafer transport operation will be integrated with an electronic process control (EPC) system according to FIG. 5 and utilized for providing process control operations, ensuring that the wafers being both processed in a timely manner and sequentially delivered to the appropriate processing departments as determined by the process flow. In some embodiments, the EPC system will also provide control and/or quality assurance and parametric data for the proper operation of the defined processing equipment. Interconnected by the wafer transport operation 702 will be the various processing departments providing, for example, photolithographic operations 704, etch operations 706, ion implant operations 708, clean-up/strip operations 710, chemical mechanical polishing (CMP) operations 712, epitaxial growth operations 714, deposition operations 716, and thermal treatments 718.

Aspects of this description relate to a method of manufacturing an integrated circuit device. The method includes forming a well region having a first dopant concentration over a semiconductor substrate. The method further includes forming a stacked structure over a first region of the well region. The method further includes etching a first portion of the well region adjacent the stacked structure to form a first recess and a mesa region. The method further includes filling the first recess with an undoped epitaxial layer. The method further includes implanting a first dopant dose of a first dopant species at an implant energy into the undoped epitaxial layer to form a first doped epitaxial region. The method further includes forming a source/drain (S/D) structure over the first doped epitaxial region, wherein a second dopant concentration within the first doped epitaxial region is sufficient to shift a device junction away from the stacked structure. In some embodiments, the method further includes configuring the stacked structure as a gate all around (GAA) structure; and incorporating at least two nanosheets within the stacked structure. In some embodiments, the method further includes selecting the implant energy that produces at least a 5× variation in the second dopant concentration of the first dopant species across a thickness of the first doped epitaxial region. In some embodiments, the method further includes implanting the first dopant dose of the first dopant species at the implant energy sufficient to produce a dopant concentration gradient across the thickness of the first doped epitaxial region, wherein the dopant concentration gradient varies between 5E¹⁹ cm⁻³ and 1E²⁰ cm⁻³. In some embodiments, the first dopant species is selected from the group consisting of arsenic (As), phosphorus (P), antimony (Sb), boron (B), boron difluoride (BF₂), gallium (Ga), and combinations thereof. In some embodiments, implanting the first dopant dose comprises performing at least a portion of the implanting as a tilted implant at a tilt angle offset from perpendicular to a plane defined by a surface of the semiconductor substrate, the tilt angle satisfying 0<tilt angle≤15°. In some embodiments, etching the first portion of the well region is performed using plasma etching, reactive ion etching (RIE), or a liquid chemical etch solution. In some embodiments, filling the first recess with the undoped epitaxial layer comprises forming the undoped epitaxial layer having a central surface region that is recessed, by a recess height, relative to a plane defined by an upper surface of the mesa region.

Aspects of this description relate to a method of fabricating a nanosheet semiconductor device. The method includes forming a well region in a semiconductor substrate. The method further includes forming a nanosheet stacked structure over a first region of the well region. The method further includes recessing the well region on opposite sides of the nanosheet stacked structure to define recessed regions. The method further includes depositing an undoped epitaxial layer having a thickness within the recessed regions. The method further includes performing a halo implant of a dopant species into the undoped epitaxial layer to a depth less than the thickness of the undoped epitaxial layer, wherein the implanted dopant species within the undoped epitaxial layer forms a doped halo region; and forming a source/drain structure over the doped halo region. In some embodiments, the depth of the dopant species is less than 85% of the thickness of the undoped epitaxial layer. In some embodiments, the nanosheet stacked structure comprises at least three nanosheets. In some embodiments, the halo implant is performed using an implant dose in a range from 5×10¹³ cm⁻² to 40×10¹³ cm⁻². In some embodiments, the method further includes forming an anti-doping region in an upper portion of the well region adjacent the recessed region prior to depositing the undoped epitaxial layer, the anti-doping region having a dopant concentration between 5E18 cm⁻³ and 5E19 cm⁻³. In some embodiments, the halo implant produces a dopant concentration in the doped halo region of between 5E18 cm⁻³ and 1E20 cm⁻³. In some embodiments, the method further includes removing silicon-germanium layers from the nanosheet stacked structure to expose silicon channel layers; and forming a gate structure that encapsulates the exposed silicon channel layers.

Aspects of this description relate to a method of forming an integrated circuit device. The method includes forming a well region over a semiconductor substrate. The method further includes forming a gate stacked structure over a mesa region of the well region. The method further includes etching the well region adjacent the gate stacked structure to form a recess. The method further includes filling the recess with an undoped epitaxial layer. The method further includes implanting a dopant species into the undoped epitaxial layer to form a doped halo region. The method further includes forming a dielectric layer over the doped halo region. The method further includes forming a source/drain structure over the doped halo region such that the dielectric layer separates the source/drain structure from the doped halo region. In some embodiments, the dielectric layer comprises silicon nitride (SiN) having a thickness of about 3 nanometers (nm) to 6 nm. In some embodiments, the dielectric layer is formed over the undoped epitaxial layer before implanting the dopant species. In some embodiments, implanting the dopant species forms a first doped upper region of the doped halo region having a dopant concentration of about 1E20 cm⁻³ and a second doped lower region of the doped halo region having a dopant concentration of about 5E19 cm⁻³. In some embodiments, forming the source/drain structure comprises epitaxially growing the source/drain structure from exposed sidewalls of silicon layers of the gate stacked structure. In some embodiments,

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of manufacturing an integrated circuit device, comprising:
forming a well region having a first dopant concentration over a semiconductor substrate;
forming a stacked structure over a first region of the well region;
etching a first portion of the well region adjacent the stacked structure to form a first recess and a mesa region;
filling the first recess with an undoped epitaxial layer;
implanting a first dopant dose of a first dopant species at an implant energy into the undoped epitaxial layer to form a first doped epitaxial region; and
forming a source/drain (S/D) structure over the first doped epitaxial region, wherein a second dopant concentration within the first doped epitaxial region is sufficient to shift a device junction away from the stacked structure.

2. The method according to claim 1, further comprising:
configuring the stacked structure as a gate all around (GAA) structure; and
incorporating at least two nanosheets within the stacked structure.

3. The method according to claim 1, further comprising:
selecting the implant energy that produces at least a 5× variation in the second dopant concentration of the first dopant species across a thickness of the first doped epitaxial region.

4. The method according to claim 3, further comprising:
implanting the first dopant dose of the first dopant species at the implant energy sufficient to produce a dopant concentration gradient across the thickness of the first doped epitaxial region, wherein the dopant concentration gradient varies between 5E¹⁹ cm⁻³ and 1E²⁰ cm⁻³.

5. The method according to claim 1, wherein the first dopant species is selected from the group consisting of arsenic (As), phosphorus (P), antimony (Sb), boron (B), boron difluoride (BF₂), gallium (Ga), and combinations thereof.

6. The method according to claim 1, wherein implanting the first dopant dose comprises performing at least a portion of the implanting as a tilted implant at a tilt angle offset from perpendicular to a plane defined by a surface of the semiconductor substrate, the tilt angle satisfying 0<tilt angle≤15°.

7. The method according to claim 1, wherein etching the first portion of the well region is performed using plasma etching, reactive ion etching (RIE), or a liquid chemical etch solution.

8. The method according to claim 1, wherein filling the first recess with the undoped epitaxial layer comprises forming the undoped epitaxial layer having a central surface region that is recessed, by a recess height, relative to a plane defined by an upper surface of the mesa region.

9. A method of fabricating a nanosheet semiconductor device, comprising:
forming a well region in a semiconductor substrate;
forming a nanosheet stacked structure over a first region of the well region;
recessing the well region on opposite sides of the nanosheet stacked structure to define recessed regions;
depositing an undoped epitaxial layer having a thickness within the recessed regions;
performing a halo implant of a dopant species into the undoped epitaxial layer to a depth less than the thickness of the undoped epitaxial layer, wherein the implanted dopant species within the undoped epitaxial layer forms a doped halo region; and
forming a source/drain structure over the doped halo region.

10. The method according to claim 9, wherein the depth of the dopant species is less than 85% of the thickness of the undoped epitaxial layer.

11. The method according to claim 9, wherein the nanosheet stacked structure comprises at least three nanosheets.

12. The method according to claim 9, wherein the halo implant is performed using an implant dose in a range from 5×10¹³ cm⁻² to 40×10¹³ cm⁻².

13. The method according to claim 9, further comprising forming an anti-doping region in an upper portion of the well region adjacent the recessed region prior to depositing the undoped epitaxial layer, the anti-doping region having a dopant concentration between 5E18 cm⁻³ and 5E19 cm⁻³.

14. The method according to claim 9, wherein the halo implant produces a dopant concentration in the doped halo region of between 5E18 cm⁻³ and 1E20 cm⁻³.

15. The method according to claim 9, further comprising:
removing silicon-germanium layers from the nanosheet stacked structure to expose silicon channel layers; and
forming a gate structure that encapsulates the exposed silicon channel layers.

16. A method of forming an integrated circuit device, comprising:
forming a well region over a semiconductor substrate;
forming a gate stacked structure over a mesa region of the well region;
etching the well region adjacent the gate stacked structure to form a recess;
filling the recess with an undoped epitaxial layer;
implanting a dopant species into the undoped epitaxial layer to form a doped halo region;
forming a dielectric layer over the doped halo region; and
forming a source/drain structure over the doped halo region such that the dielectric layer separates the source/drain structure from the doped halo region.

17. The method according to claim 16, wherein the dielectric layer comprises silicon nitride (SiN) having a thickness of about 3 nanometers (nm) to 6 nm.

18. The method according to claim 16, wherein the dielectric layer is formed over the undoped epitaxial layer before implanting the dopant species.

19. The method according to claim 16, wherein implanting the dopant species forms a first doped upper region of the doped halo region having a dopant concentration of about 1E20 cm⁻³ and a second doped lower region of the doped halo region having a dopant concentration of about 5E19 cm⁻³.

20. The method according to claim 16, wherein forming the source/drain structure comprises epitaxially growing the source/drain structure from exposed sidewalls of silicon layers of the gate stacked structure.
